(19) United States
(12) Patent Application Publication
(10) Pub. No.: US 2026/0031746 A1
(43) Pub. Date: Jan. 29, 2026

(54) PIEZO ACTUATOR SYSTEM AND OPERATING METHOD THEREOF

(71) Applicant: Samsung Electro-Mechanics Co., Ltd., Suwon-si (KR)

(72) Inventors: Dooseub SHIN, Suwon-si (KR); Donghoon LEE, Suwon-si (KR); Sanghyun JI, Suwon-si (KR); Chueljin PARK, Suwon-si (KR)

(73) Assignee: Samsung Electro-Mechanics Co., Ltd., Suwon-si (KR)

(21) Appl. No.: 18/984,949

(22) Filed: Dec. 17, 2024

(30) Foreign Application Priority Data
Jul. 24, 2024 (KR) 10-2024-0097976

(51) Int. Cl. H02N 2/06; G02B 7/04; H02N 2/02

(52) U.S. Cl. CPC H02N 2/067; G02B 7/04; H02N 2/025

(57) ABSTRACT

A piezo actuator system includes a piezo actuator; and a driving circuit configured to apply a pulse width modulation (PWM) voltage waveform to the piezo actuator. An envelope of the PWM voltage waveform includes a first period in which a first voltage rising with a first slope is applied, a second period in which a second voltage rising with a second slope is applied, and a third period in which a third voltage rising with a third slope is applied. The third slope is greater than the second slope.

### CROSS-REFERENCE TO RELATED APPLICATIONS

This application claims the benefit under 35 USC 119 (a) of Korean Patent Application No. 10-2024-0097976 filed on Jul. 24, 2024, in the Korean Intellectual Property Office, the entire disclosure of which is incorporated herein by reference for all purposes.

### BACKGROUND

### 1. Field

The following description relates to a piezo actuator system and an operating method thereof.

### 2. Description of the Related Art

The camera module is a main component that provides photos and images in mobile devices such as smartphones, vehicles, and smart home appliances. The camera module may include an auto-focus (AF) function that automatically focuses on a subject, an optical image stabilization (OIS) function that adjusts a camera shake, an IRIS function that controls the amount of light, and an optical zoom function that enlarges and captures a distant subject. To implement these functions, an actuator is used to apply force to a lens unit.

Typically, a voice coil motor (VCM) actuator that utilizes a magnetic force between a coil and a magnet is used. The VCM actuator has the drawbacks of high power consumption, small driving torque relative to its size, and short driving distance. This may make the VCM actuator unsuitable for the trend toward larger image sensor and larger lens unit.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a piezo actuator system includes a piezo actuator; and a driving circuit configured to apply a pulse width modulation (PWM) voltage waveform to the piezo actuator. An envelope of the PWM voltage waveform includes a first period in which a first voltage rising with a first slope is applied, a second period in which a second voltage rising with a second slope is applied, and a third period in which a third voltage rising with a third slope is applied. The third slope is greater than the second slope.

The envelope of the PWM voltage waveform may further include a fourth period in which a fourth voltage falling with a fourth slope is applied, and a fifth period in which a fifth voltage falling with a fifth slope is applied.

The second slope may be smaller than the first slope.

The first period to the fifth period may be sequentially continuous periods.

The PWM voltage waveform may include a first pulse in which is applied in the first period, and the first pulse may start a movement of a moving unit.

In the second period, the envelope of the PWM voltage waveform may gradually rise with the second slope.

In the fourth period, the envelope of the PWM voltage waveform may gradually fall with the fourth slope.

In another general aspect, an operating method of a piezo actuator system includes a piezo actuator and a driving circuit configured to apply a pulse width modulation (PWM) voltage waveform to the piezo actuator. The operating method includes, in a first period, applying a first pulse having a first voltage to the piezo actuator; in second period, applying a plurality of second pulses having second voltages greater than the first voltage to the piezo actuator, wherein the second voltages gradually increase over time from the first voltage; and in third period, applying a third pulse having a third voltage greater than the second voltages to the piezo actuator. An envelope of the PWM voltage waveform has a first slope in the first period, a second slope in the second period, and a third slope greater than the second slope in the third period.

The operating method further includes, in fourth period, applying a plurality of fourth pulses having fourth voltages smaller than the third voltage to the piezo actuator. The fourth voltages may gradually decrease over time from the third voltage.

The second slope may be smaller than the first slope.

The first period to the fourth period may be sequentially continuous periods.

The first pulse may start a movement of a moving unit.

In the second period, the envelope of the PWM voltage waveform may gradually increase with the second slope.

Other features and aspects will be apparent from the following detailed description, the drawings, and the claims.

### BRIEF DESCRIPTION OF THE DRAWINGS

FIG. 1 is a block diagram showing a piezo actuator system 1000 according to one embodiment.

FIG. 2 is a drawing conceptually illustrating a configuration of the piezo actuator 200 according to one embodiment.

FIG. 3 is a drawing showing a driving voltage waveform according to one embodiment.

FIG. 4 is a drawing showing a driving voltage waveform according to another embodiment.

FIG. 5 is a drawing showing the envelope and a slope of the envelope for the driving voltage waveform of FIG. 4

FIG. 6 is a drawing showing another example of the envelope of the driving voltage waveform.

FIG. 7 is a block diagram showing a camera module 7000 according to one embodiment.

FIG. 8A is a graph showing a noise measured in the rising period through an experiment, and FIG. 8B is a graph showing a noise measured in the falling period through an experiment

Throughout the drawings and the detailed description, the same reference numerals refer to the same elements. The drawings may not be to scale, and the relative sizes, proportions, and depictions of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

In this application, an RF signal includes Wi-Fi (IEEE 802.11 family, etc.), WiMAX (IEEE 802.16 family, etc.), IEEE 802.20, LTE (Long-Term Evolution), EV-DO, HSDPA, HSUPA, HSPA, HSPA+, EDGE, GSM, GPS, GPRS, CDMA, TDMA, DECT, Bluetooth, 3G, 4G, 5G, and any other wireless and wired protocols designated hereafter, but is not limited thereto.

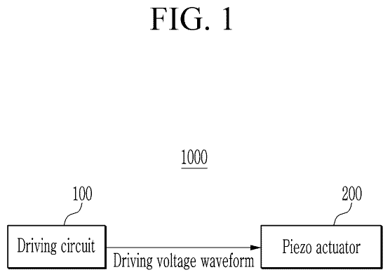

FIG. 1 is a block diagram showing a piezo actuator system 1000 according to one embodiment.

As shown in FIG. 1, the piezo actuator system 1000 according to one embodiment may include a driving circuit 100 and a piezo actuator 200.

The driving circuit 100 may generate a driving voltage waveform that operates the piezo actuator 200, and the generated driving voltage waveform may be applied to the piezo actuator 200. Examples of driving voltage waveforms include a sawtooth voltage waveform and a pulse width modulation (PWM) voltage waveform. The specific method by which the driving circuit 100 generates the driving voltage waveform is known to a person with ordinary skill in the art, so a detailed description is omitted.

The piezo actuator 200 may perform an operation in response to the driving voltage waveform applied from the driving circuit 100. The piezo actuator 200 may move a moving unit in response to the driving voltage waveform. The piezo actuator 200 is in contact with the moving unit. The moving unit is an object moved by a piezo actuator 200, and as an example, the moving unit may be a lens unit included in a camera module.

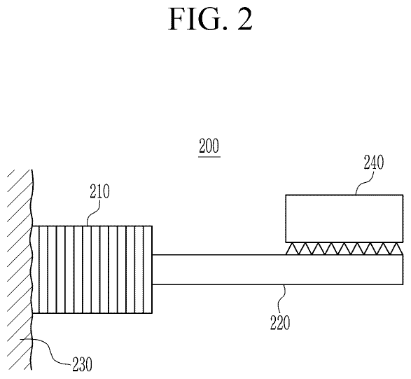

FIG. 2 is a drawing conceptually illustrating a configuration of the piezo actuator 200 according to one embodiment.

As shown in FIG. 2, the piezo actuator 200 according to one embodiment may include a piezo element 210 and a rod 220.

The piezo element 210 is an element that deforms when voltage is applied and may include a piezoelectric material having a piezoelectric effect. As an example, the piezo element 210 may be a device having a laminated ceramic layer. The piezo element 210 may include a pair of electrodes (not shown in FIG. 2), one electrode being a ground electrode and the other electrode being a driving electrode. The driving voltage waveform generated in the driving circuit 100 may be applied to the driving electrode.

Referring to FIG. 2, one end of the piezo element 210 may be fixed to a fixed member 230, and the rod 220 may be attached to the other end of the piezo element 210. The fixed member 230 may be a predetermined fixed member present in a product in which the piezo actuator 200 is mounted. As an example, the other end of the piezo element 210 and the rod 220 may be connected to each other via an adhesive. The rod 220 may be a carbon fiber reinforced polymer (CFRP) material.

The moving unit 240 is installed on the rod 220, and a friction pad may be positioned at the part where the moving unit 240 and the rod 220 come into contact with each other. As an example, the moving unit 240 can be installed on the rod 220 by preload. Here, the moving unit 240 is an object moved by the piezo actuator 200, and as an example, the moving unit 240 may be a lens unit included in a camera module.

Piezo element 210 is an element that contracts and expands according to the driving voltage waveform. When the driving voltage waveform increases slowly, the piezo element 210 also expands slowly. At this time, the moving unit 240 moves together with the rod 220. Meanwhile, when the driving voltage waveform decreases rapidly, the piezo element 210 contracts rapidly. At this time, due to inertia, the moving unit 240 slides on the rod 220 and remains in that position. This driving principle is called the Smooth Impact Drive Mechanism (SIDM) drive.

By repeating this driving, the moving distance of the moving unit 240 may be increased. The SIDM driving method may also be applied to the following embodiments, and a PWM voltage waveform may be used as the driving voltage waveform for convenience of explanation.

When the piezo actuator 200 is driven, friction occurs between the piezo element 210 and the moving unit 240, and noise may be generated due to this friction. When the moving unit 240 starts moving and stops, a lot of noise may occur. Also, during a period in which the moving unit 240 moves at a constant speed, less noise may be generated. Accordingly, in order to reduce noise, an appropriate design of the driving voltage waveform applied to the piezo actuator 200 at the starting point and stopping point of the moving part 240 may be desired. Below, the driving voltage waveform for reducing noise is described.

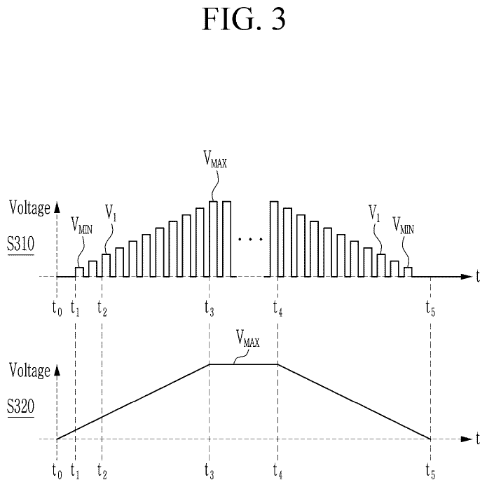

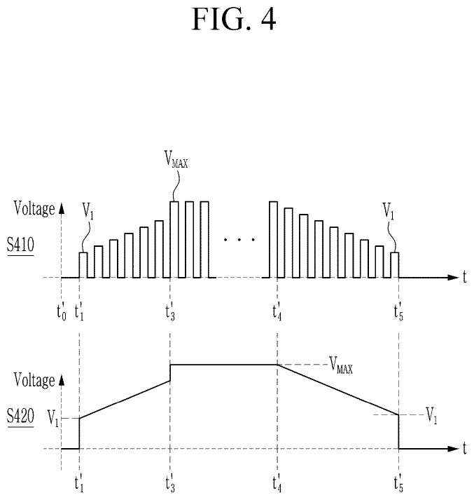

FIG. 3 is a drawing showing a driving voltage waveform according to one embodiment. In FIG. 3, S310 represents the driving voltage waveform, and S320 represents an envelope for the driving voltage waveform.

Referring to S310 of FIG. 3, the driving voltage waveform according to one embodiment may be a PWM voltage waveform. The PWM voltage waveform has a plurality of pulses, and the voltage value of each pulse is referred to as the ‘pulse voltage value’.

To reduce driving noise, the voltage value of the plurality of pulses may gradually increase and then gradually decrease. At the point when the moving unit 240 starts to move, the voltage value of the plurality of pulses may gradually increase, and at the point when the moving unit 240 stops, the voltage value of the plurality of pulses may gradually decrease.

In FIG. 3, t0 is a time point at which the driving voltage waveform is first applied to the piezo actuator 200 to move the moving unit 240. At t0, the driving voltage waveform may not have a pulse.

At t1, the first pulse of the driving voltage waveform may be applied to the piezo actuator 200. The voltage value of the first pulse may be VMIN. When the first pulse having VMIN is applied to the piezo actuator 200, the piezo element 210 may not expand or contract. That is, when the first pulse is applied to the piezo actuator 200, the moving unit 240 may not move. Here, the voltage value VMIN of the first pulse may be less than a minimum voltage value desired to operate the piezo element 210.

After the first pulse is applied, a pulse having a gradually increasing voltage value may be applied to the piezo actuator 200. At t2, a pulse having V1 value may be applied to the piezo actuator 200. In response to the pulse having the V1 value, the piezo element 210 may start expansion and contraction. By the pulse having the V1 value, the moving unit 240 may start to move. That is, when the pulse having the V1 value is applied to the piezo actuator 200, a static friction of the moving unit 240 may be changed into a dynamic friction.

Here, the V1 value may be a minimum voltage value desired to operate the piezo element 210.

From t2 to t3, a plurality of pulses having gradually increasing voltage values may be applied to the piezo actuator 200. Due to these pulses, rapid speed changes of the moving unit 240 may not occur and driving noise may be reduced.

At t3, a pulse having VMAX value may be applied. Also, from t3 to t4, a plurality of pulses having VMAX value may be applied to the piezo actuator 200. Here, the VMAX value may be the most suitable voltage value desired to operate the piezo actuator 200. Due to the plurality of pulses having a VMAX value, the piezo element 210 repeats expansion and contraction, and the moving unit 240 may move. In the period from t3 to t4, the moving unit 240 may move at a constant speed and generate very little noise.

From t4 to t5, a plurality of pulses having a gradually decreasing voltage value may be applied to the piezo actuator 200. Due to these pulses, rapid speed changes of the moving unit 240 may not occur in the period where the moving unit 240 stops, and driving noise may be reduced. Here, the piezo element 210 may expand and contract in response to the pulse having the V1 value, but the piezo element 210 may not expand and contract in response to the pulse having a VMIN value.

Meanwhile, from an envelope perspective, the driving voltage waveform S310 is explained as follows.

Referring to S320, an envelope of the driving voltage waveform can gradually increase and then gradually decrease.

From t0 to t3, an envelope of the driving voltage waveform increases gradually with a predetermined slope. Due to this, rapid speed changes of the moving unit 240 may not occur and driving noise may be reduced.

From t3 to t4, an envelope of the driving voltage waveform remains at the VMAX value.

From t4 to t5, an envelope of the driving voltage waveform gradually decreases with a predetermined slope.

Due to this, in the period where the moving part 240 stops, rapid speed changes of the moving unit 240 may not occur, and driving noise may be reduced.

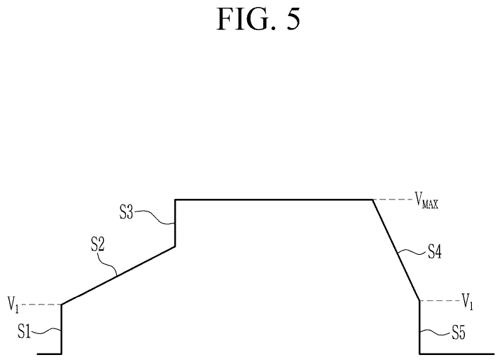

In order to further reduce the driving noise through the driving voltage waveform of FIG. 3, it may be desirable to increase the period from t0 to t3 (i.e., the rising period taken to reach from 0 V voltage to V_{MAX} voltage) and the period from t4 to t5 (i.e., the falling period taken to reach from V_{MAX} voltage to 0V voltage). That is, in the envelope S320 of the driving voltage waveform, it may be desirable to reduce (decrease) the rising slope and falling slope. However, reducing these rising and falling slopes may cause the problem of increasing the entire application time of the driving voltage waveform. Below, referring to FIG. 4 and FIG. 5, a driving voltage waveform that improves these problems is described.

FIG. 4 is a drawing showing a driving voltage waveform according to another embodiment. In FIG. 4, S410 represents the driving voltage waveform, and S420 represents the envelope for the driving voltage waveform.

Referring to S410 of FIG. 4, the driving voltage waveform according to another embodiment may be a PWM voltage waveform. To reduce driving noise, a voltage value of a plurality of pulses may gradually increase and then gradually decrease. At the point when the moving unit 240 starts to move, the voltage value of the plurality of pulses may gradually increase, and at the point when the moving unit 240 stops, the voltage value of the plurality of pulses may gradually decrease. Here, the driving voltage waveform according to another embodiment may reduce an application time through a period where the voltage value of the pulse rises or falls rapidly.

In FIG. 4, t0′ is the time point at which the driving voltage waveform is first applied to the piezo actuator 200 to move the moving unit 240. At t0′, the driving voltage waveform may not have a pulse.

At t1′, the first pulse of the driving voltage waveform S410 may be applied to the piezo actuator 200. The voltage value of the first pulse may be V1. In response to the first pulse having the V1 value, the piezo element 210 may start expansion and contraction. By the first pulse having the V1 value, the piezo element 210 may start expansion and contraction. That is, by the first pulse having the V1 value, a static friction of the moving unit 240 may be changed into a dynamic friction. The moving unit 240 may not move due to the first pulse of the driving voltage waveform S310 of FIG. 3, but the moving unit 240 may move due to the first pulse of the driving voltage waveform S410 of FIG. 4.

After the first pulse is applied, a pulse having a gradually increasing voltage value may be applied to the piezo actuator 200. That is, from t1′ to t3′, a plurality of pulses having gradually increasing voltage values may be applied to the piezo actuator 200. Due to these pulses, rapid speed changes of the moving unit 240 may not occur and driving noise may be reduced.

At t3′, a pulse with the V_{MAX} value is applied. Also, from t3′ to t4′, a plurality of pulses having V_{MAX} value may be applied to the piezo actuator 200. Here, the V_{MAX} value may be the most suitable voltage value desired to operate the piezo actuator 200. Due to a plurality of pulses having a V_{MAX} value, the piezo element 210 repeats expansion and contraction, and the moving unit 240 may move. In the period from t3′ to t4′, the moving unit 240 may move at a constant speed and generate very little noise.

From t4′ to t5′, a plurality of pulses having a gradually decreasing voltage value can be applied to the piezo actuator 200. Due to these pulses, rapid speed changes of the moving unit 240 may not occur in the period where the moving unit 240 stops, and driving noise may be reduced. Here, the last pulse is a pulse having the V1 value, and this pulse causes the piezo element 210 to expand and contract.

Meanwhile, from an envelope perspective, the driving voltage waveform S410 is explained as follows.

Referring to S420, the envelope of the driving voltage waveform rises sharply at t1′. The envelope for the driving voltage waveform in FIG. 3 increases gradually at t1, but the envelope for the driving voltage waveform in FIG. 4 increases sharply at t1′. The piezo actuator 200 may not operate by a pulse having a voltage lower than the V1 voltage (i.e., the moving unit 240 does not move). Accordingly, the envelope of the driving voltage waveform of FIG. 4 may generate less driving noise even if it rises sharply from 0V to V1 voltage.

From t1′ to t3′, an envelope of the driving voltage waveform increases gradually with a predetermined slope. Due to this, in the period where the moving unit 240 starts to move, a sudden change in speed of the moving unit 240 may not occur, and driving noise may be reduced.

At t3′, an envelope of the driving voltage waveform rises sharply to the V_{MAX} voltage. The envelope of the driving voltage waveform in FIG. 3 increases gradually until t3, but the envelope of the driving voltage waveform in FIG. 4 increases sharply at t3′. Since the moving unit 240 has already moved before t3′, less driving noise may occur even if the envelope of the driving voltage waveform rises sharply at t3′.

From t3′ to t4′, an envelope of the driving voltage waveform remains at the V_{MAX} value.

From t4′ to t5′, an envelope of the driving voltage waveform gradually decreases with a predetermined slope. That is, from t4′ to t5′, the envelope of the driving voltage waveform may gradually decrease from the V_{MAX} voltage to the V1 voltage. Due to this, in the period where the moving unit 240 stops, rapid speed changes of the moving unit 240 may not occur, and driving noise may be reduced.

At t5′, an envelope of the driving voltage waveform drops sharply. The envelope for the driving voltage waveform in FIG. 3 decreases gradually until t5, but the envelope for the driving voltage waveform in FIG. 4 decreases sharply at t5′. That is, at t5′, the envelope of the driving voltage waveform of FIG. 4 may drop sharply from V1 voltage to 0V. The piezo actuator 200 may not operate by a pulse having a voltage lower than the V1 voltage (i.e., the moving unit 240 does not move). Accordingly, the envelope of the driving voltage waveform of FIG. 4 may generate less driving noise even if it drops sharply from the V1 voltage to the 0V voltage.

According to another embodiment, the envelope of the driving voltage waveform may rise sharply at t1′, rise sharply at t3′, and fall (drop) sharply at t5′. Through this, the driving voltage waveform according to another embodiment may reduce the driving noise and simultaneously reduce the entire application time.

FIG. 5 is a drawing showing the envelope and a slope of the envelope for the driving voltage waveform of FIG. 4.

As shown in FIG. 5, the envelope of the driving voltage waveform according to another embodiment may include a first period in which a first voltage rising with a first slope S1 is applied, a second period in which a second voltage rising with a second slope S2 is applied, and a third period in which a third voltage rising with a third slope S3 is applied. Here, the third slope S3 may be greater than the second slope S2. The second slope S2 may be smaller than the first slope S1.

Also, the envelope of the driving voltage waveform according to another embodiment may further include a fourth period in which a fourth voltage falling (decreasing) with a fourth slope S4 is applied, and a fifth period in which a fifth voltage falling (decreasing) with a fifth slope S5 is applied. Here, the fifth slope S5 may be greater than the fourth slope S4. In an example, the first period to the fifth period are sequentially continuous periods.

In FIG. 5, in the period rising from 0 V voltage to V_{MAX} voltage, the envelope of the driving voltage waveform according to another embodiment has the first slope S1, the second slope S2, and the third slope S3. In contrast, the envelope of the driving voltage waveform in FIG. 3 has only one slope in the period rising from the 0 V voltage to the V_{MAX} voltage. Through this, compared to the driving voltage waveform of FIG. 3, the driving voltage waveform of FIG. 4 may reduce the rising period (the time it takes to reach from 0 V to V_{MAX} voltage). Due to this reduction in the rising period, the entire application time of the driving voltage waveform may be reduced.

In FIG. 5, in the period decreasing from the V_{MAX} voltage to the 0 V voltage, the envelope of the driving voltage waveform according to another embodiment has the fourth slope S4 and the fifth slope S5. In contrast, the envelope of the driving voltage waveform in FIG. 3 has only one slope in the period decreasing from the V_{MAX} voltage to the 0V voltage. Through this, compared to the driving voltage waveform of FIG. 3, the driving voltage waveform of FIG. 4 may reduce the falling (decreasing) period (the time it takes to reach 0V from VMAX voltage). Due to this reduction in the falling period, the entire application time of the driving voltage waveform can be reduced.

Meanwhile, in the driving voltage waveform of FIG. 3 and the driving voltage waveform of FIG. 4, when the rising period (the time taken to reach the V_{MAX} voltage from 0 V) is set to the same value, the second slope S2 of the driving voltage waveform of FIG. 4 may be set to a smaller value than the rising slope of the driving voltage waveform of FIG. 3 (the slope in the period from t0 to t3). Through this, the driving voltage waveform of FIG. 4 may further reduce noise than the driving voltage waveform of FIG. 3.

In the driving voltage waveform of FIG. 3 and the driving voltage waveform of FIG. 4, when the falling period (the time it takes to reach from the V_{MAX} voltage to the 0 V voltage) is set to the same value, the fourth slope S4 of the driving voltage waveform of FIG. 4 may be set to a smaller value than the falling slope of the driving voltage waveform of FIG. 3 (the slope in the period from t4 to t5). Through this, the driving voltage waveform of FIG. 4 may further reduce noise than the driving voltage waveform of FIG. 3.

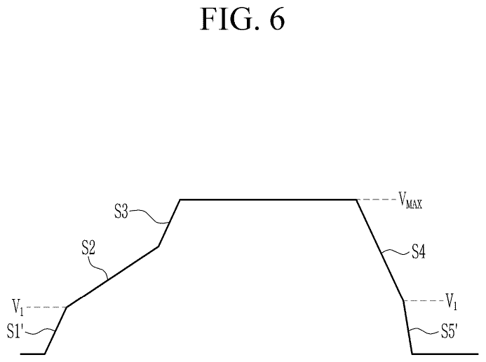

FIG. 6 is a drawing showing another example of the envelope of the driving voltage waveform.

The first slope S1 in FIG. 5 may conceptually be a positive infinity (+∞) value. However, in practice, the first slope S1 in FIG. 5 may have a finite value, not positive infinity. As shown in FIG. 6, the envelope of the driving voltage waveform can have a first period that rises with a S1′ slope. Here, S1′ is a finite value and may be less than S1.

The fifth slope S5 in FIG. 5 may conceptually be a negative infinity (−∞) value. However, in practice, the fifth slope S5 of FIG. 5 may have a finite value, not negative infinity. As shown in FIG. 6, the envelope of the driving voltage waveform may have a fifth period that decreases (falls) with a S5′ slope. Here, S5′ is a finite value and may be less than S5.

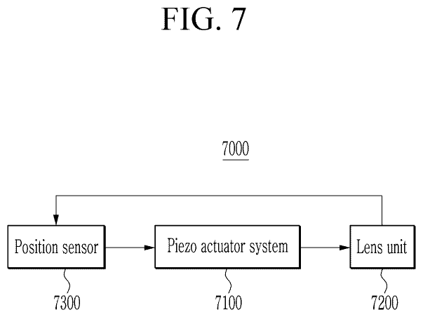

FIG. 7 is a block diagram showing a camera module 7000 according to one embodiment.

As shown in FIG. 7, the camera module 7000 according to one embodiment may include a piezo actuator system 7100, a lens unit 7200, and a position sensor 7300.

The piezo actuator system 7100 may be the piezo actuator system 1000 of FIG. 1. Here, the driving voltage waveform applied to the piezo actuator can be the driving voltage waveform of FIG. 3 or FIG. 4.

The lens unit 7200 includes at least one lens, and light passing through the lens unit 7200 may be transmitted to an image sensor (not shown). The lens unit 7200 may be controlled and movable by the piezo actuator system 7100. Through this, the camera module 7000 can perform AF function, OIS function, and zoom function.

Position sensor 7300 may be a sensor that detects the position of lens unit 7200. The position sensor 7300 may output the detected position information of the lens unit 7200 to the piezo actuator system 7100. The piezo actuator system 7100 may generate a driving voltage waveform based on the position information of the lens unit 7200 received from the position sensor 7300. To explain in more detail, the piezo actuator system 7100 may calculate an optimal driving voltage waveform to move the lens unit 7200 to a target position based on the position information of the lens unit 7200 received from the position sensor 7300. The driving voltage waveform may be the driving voltage waveform of FIG. 3 or the driving voltage waveform of FIG. 4.

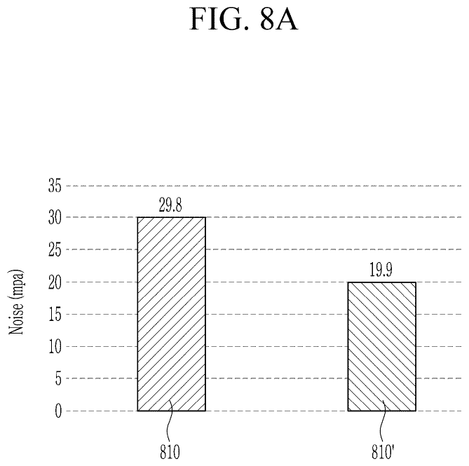

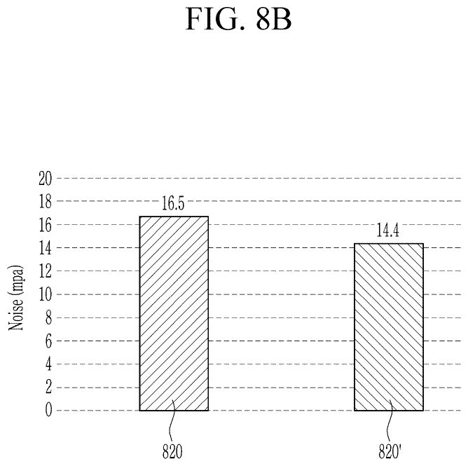

FIG. 8A is a graph showing a noise measured in the rising period through an experiment. FIG. 8B is a graph showing a noise measured in the falling period through an experiment.

In FIG. 8A and FIG. 8B, the vertical axis represents an average value for noise values measured in multiple experiments.

In FIG. 8A, 810 represents the noise value for the rising period (the period rising from 0 V to V_{MAX} voltage) in the driving voltage waveform of FIG. 3.

810′ represents the noise value for the rising period (the period rising from 0V to V_{MAX} voltage) in the driving voltage waveform of FIG. 4. Referring to FIG. 8A, in the case of the driving voltage waveform of FIG. 3, a noise of 29.8 mpa (mili-pascal) occurs in the rising period, and in the case of the driving voltage waveform of FIG. 4, a noise of 19.9 mpa occurs in the rising period. That is, in the rising period, the driving voltage waveform of FIG. 4 generates less noise than the driving voltage waveform of FIG. 3.

In FIG. 8B, 820 represents the noise value for the falling (decreasing) period (the period falling from V_{MAX} voltage to 0V voltage) in the driving voltage waveform of FIG. 3. 820′ represents the noise value for the falling (decreasing) period (the period falling from V_{MAX} voltage to 0V voltage) in the driving voltage waveform of FIG. 4. Referring to FIG. 8B, in the case of the driving voltage waveform of FIG. 3, a noise of 16.5 mpa occurs in the falling period, and in the case of the driving voltage waveform of FIG. 4, a noise of 14.4 mpa occurs in the falling period. That is, in the falling period, the driving voltage waveform of FIG. 4 generates less noise than the driving voltage waveform of FIG. 3.

As described above, according to at least one aspect, by varying the slope of the envelope of the PWM driving waveform, driving noise may be reduced.

While specific examples have been shown and described above, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed to have a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A piezo actuator system comprising:
a piezo actuator; and
a driving circuit configured to apply a pulse width modulation (PWM) voltage waveform to the piezo actuator,
wherein an envelope of the PWM voltage waveform comprises a first period in which a first voltage rising with a first slope is applied, a second period in which a second voltage rising with a second slope is applied, and a third period in which a third voltage rising with a third slope is applied, and the third slope is greater than the second slope.

2. The piezo actuator system of claim 1, wherein
the envelope of the PWM voltage waveform further comprises a fourth period in which a fourth voltage falling with a fourth slope is applied, and a fifth period in which a fifth voltage falling with a fifth slope is applied.

3. The piezo actuator system of claim 1, wherein
the second slope is smaller than the first slope.

4. The piezo actuator system of claim 2, wherein
the first period to the fifth period are sequentially continuous periods.

5. The piezo actuator system of claim 1, wherein
the PWM voltage waveform comprises a first pulse in which is applied in the first period, and
the first pulse starts a movement of a moving unit.

6. The piezo actuator system of claim 1, wherein
in the second period, the envelope of the PWM voltage waveform gradually rises with the second slope.

7. The piezo actuator system of claim 2, wherein
in the fourth period, the envelope of the PWM voltage waveform gradually falls with the fourth slope.

8. An operating method of a piezo actuator system, the piezo actuator system comprising a piezo actuator and a driving circuit configured to apply a pulse width modulation (PWM) voltage waveform to the piezo actuator, the operating method comprising:
in a first period, applying a first pulse having a first voltage to the piezo actuator;
in second period, applying a plurality of second pulses having second voltages greater than the first voltage to the piezo actuator, wherein the second voltages gradually increase over time from the first voltage; and
in third period, applying a third pulse having a third voltage greater than the second voltages to the piezo actuator,
wherein an envelope of the PWM voltage waveform has a first slope in the first period, a second slope in the second period, and a third slope greater than the second slope in the third period.

9. The operating method of claim 8, further comprising
in fourth period, applying a plurality of fourth pulses having fourth voltages smaller than the third voltage to the piezo actuator, wherein the fourth voltages gradually decrease over time from the third voltage.

10. The operating method of claim 8, wherein
the second slope is smaller than the first slope.

11. The operating method of claim 9, wherein
the first period to the fourth period are sequentially continuous periods.

12. The operating method of claim 8, wherein
the first pulse starts a movement of a moving unit.

13. The operating method of claim 8, wherein
in the second period, the envelope of the PWM voltage waveform gradually increases with the second slope.
